(19) United States
(12) Patent Application Publication
(10) Pub. No.: US 2020/0321491 A1
(43) Pub. Date: Oct. 8, 2020

(54) NITRIDE SEMICONDUCTOR ULTRAVIOLET LIGHT EMITTING DEVICE AND METHOD FOR MANUFACTURING SAME

(71) Applicants: Soko Kagaku Co., Ltd., Ishikawa (JP); AGC INC., TOKYO (JP)

(72) Inventors: Akira HIRANO, Aichi (JP); Kiho YAMADA, Aichi (JP); Ko AOSAKI, Tokyo (JP)

(73) Assignees: Soko Kagaku Co., Ltd., Ishikawa (JP); AGC INC., TOKYO (JP)

(21) Appl. No.: 16/301,373

(22) PCT Filed: Feb. 27, 2017
(86) PCT No.: PCT/JP2017/007342

§ 371 Date: Nov. 13, 2018

(30) Foreign Application Priority Data
Jun. 3, 2016 (JP) 2016-112084

(51) Int. Cl. H01L 33/22; H01L 33/00; H01L 33/32; H01L 33/56

(52) U.S. Cl. CPC H01L 33/22; H01L 33/0095; H01L 33/54; H01L 33/56; H01L 2933/005; H01L 33/32

(57) ABSTRACT

Provided is an ultraviolet light emitting device having high quality and high reliability that prevents deterioration in electrical characteristics caused by a photochemical reaction of a non-bonding amorphous fluororesin, decomposition or the like of the amorphous fluororesin, and peeling off of the amorphous fluororesin. A nitride semiconductor ultraviolet light emitting device 1 includes a base 30, a nitride semiconductor ultraviolet light emitting element flip-chip mounted on the base 30, and an amorphous fluororesin 40 that is in direct contact with the nitride semiconductor ultraviolet light emitting element for covering. The nitride semiconductor ultraviolet light emitting element includes a sapphire substrate 11, a plurality of AlGaN-based semiconductor layers 12 laminated on the main surface of the sapphire substrate 11, an n-electrode 13, and a p-electrode 14. A terminal functional group of the amorphous fluororesin 40 is a perfluoroalkyl group, and the amorphous fluororesin 40 enters into depressions formed on the side surface of the sapphire substrate 11.

### TECHNICAL FIELD

The present invention relates to a nitride semiconductor ultraviolet light emitting device, and more particularly to a rear surface emission type nitride semiconductor ultraviolet light emitting device that is sealed with an amorphous fluororesin and extracts light having a light emission center wavelength of about 350 nm or less from the rear surface side of a substrate.

### BACKGROUND ART

Conventionally, there are a large number of nitride semiconductor light emitting elements such as light emitting diodes (LEDs) or semiconductor lasers in which a light emitting element structure including a plurality of nitride semiconductor layers is formed on a substrate such as sapphire by epitaxial growth (for example, see Non-Patent Documents 1 and 2 below). The nitride semiconductor layer is represented by the general formula Al_{1-x-y}GaₓIn_{y}N (0≤x≤1, 0≤y≤1, 0≤x+y≤1).

The light emitting element structure has a double-hetero structure in which an active layer is interposed between an n-type nitride semiconductor layer and a p-type nitride semiconductor layer. The active layer includes a nitride semiconductor layer having a single-quantum-well (SQW) structure or a multi-quantum-well (MQW) structure. When the active layer is an AlGaN-based semiconductor layer, a band gap energy can be adjusted within a range of lower and upper limits of band gap energies that can be taken by GaN and AlN respectively (about 3.4 eV and about 6.2 eV) by adjusting an AlN molar fraction (also referred to as an Al composition ratio). Thus, it is possible to obtain an ultraviolet light emitting element having a light emission wavelength of about 200 nm to about 365 nm. Specifically, when a forward current flows from the p-type nitride semiconductor layer to the n-type nitride semiconductor layer, light emission equivalent to the band gap energy occurs in the active layer.

Meanwhile, flip-chip mounting has been generally employed as a way of mounting a nitride semiconductor ultraviolet light emitting element (for example, see FIG. 4 or the like in Patent Document 1 below). In the flip-chip mounting, light emitted from an active layer is transmitted through an AlGaN-based nitride semiconductor, a sapphire substrate, or the like having a band gap energy greater than the active layer to be extracted from the element. For that reason, in the flip-chip mounting, the sapphire substrate faces upward, and p-side and n-side electrode surfaces formed on the upper surface side of a chip face downward. The electrode surfaces on the chip side are electrically and physically bonded via metal bumps formed on the electrode surfaces to electrode pads on a package component side such as a submount.

Generally, as disclosed in FIGS. 4, 6, and 7, or the like in Patent Document 2 below or FIGS. 2, 4, and 6, or the like in Patent document 3 below, the nitride semiconductor ultraviolet light emitting element is practically used in a state of being sealed with an ultraviolet-transparent resin such as a fluorine-based resin or a silicone resin. The sealing resin protects an ultraviolet light emitting element within the resin from the outside atmosphere, to prevent deterioration in the light emitting element caused by the entrance of water, oxidization, or the like. Furthermore, the sealing resin is sometimes provided as a refractive index difference mitigation material for improving light extraction efficiency by mitigating a light reflection loss caused by a refractive index difference between a light condensing lens and an ultraviolet light emitting element or a refractive index difference between a space to be irradiated with ultraviolet light and an ultraviolet light emitting element. The surface of the sealing resin may be formed into a light condensing curved surface such as a spherical surface to improve irradiation efficiency.

### PRIOR ART DOCUMENTS

### Patent Documents

PATENT DOCUMENT 1: WO 2014/178288

PATENT DOCUMENT 2: Japanese Patent Application Publication No. 2007-311707

PATENT DOCUMENT 3: U.S. Patent Application Publication No. 2006/0138443

PATENT DOCUMENT 4: Japanese Patent Application Publication No. 2006-348088

### Non-Patent Documents

NON-PATENT DOCUMENT 1: Kentaro Nagamatsu, et al., “High-efficiency AlGaN-based UV light emitting diode on laterally overgrown AlN”, Journal of Crystal Growth, 2008, 310, pp. 2326-2329

NON-PATENT DOCUMENT 2: Shigeaki Sumiya, et al., “AlGaN-Based Deep Ultraviolet Light emitting Diodes Grown on Epitaxial AlN/Sapphire Templates”, Japanese Journal of Applied Physics, Vol. 47, No. 1, 2008, pp. 43-46

NON-PATENT DOCUMENT 3: Kiho Yamada, et al., “Development of underfilling and encapsulation for deep-ultraviolet LEDs”, Applied Physics Express, 8, 012101, 2015

### SUMMARY OF THE INVENTION

### Problems to be Solved by the Invention

As described above, it has been proposed to use a fluorine-based resin, a silicone resin, and the like as a sealing resin for an ultraviolet light emitting element. However, it has been found that, if the silicone resin is exposed to a large amount of high energy ultraviolet light, deterioration in the silicone resin is prompted. In particular, there has been prompted lower wavelength and higher output of the ultraviolet light emitting element, and thus the deterioration in the sealing resin caused by exposure to the ultraviolet light tends to be accelerated. The heat generation is also increased by increase in consumption power associated with higher output, which disadvantageously also leads to the deterioration in the sealing resin.

While it has been known that a fluorine-based resin has excellent heat resistance and high ultraviolet resistance, a general fluororesin such as polytetrafluoroethylene is opaque. The fluorine-based resin has linear and rigid polymer chains and is easily crystallized. Consequently, there are a crystalline portion and an amorphous portion in a mixed manner in the fluororesin. Light is scattered at an interface between the crystalline portion and the amorphous portion, and thus the fluororesin is opaque.

For example, it is proposed in Patent Document 4 above that an amorphous fluororesin is used as a sealing resin of an ultraviolet light emitting element to improve the transparency of the amorphous fluororesin to ultraviolet light. Examples of the amorphous fluororesin include one with a fluororesin of a crystalline polymer copolymerized and made amorphous as a polymer alloy, a copolymer of perfluorodioxole (trade name Teflon AF (registered trademark) manufactured by du Pont) and a cyclopolymerized polymer of perfluorobutenyl vinyl ether (trade name CYTOP (registered trademark) manufactured by Asahi Glass Co., Ltd.). The latter fluororesin of the cyclopolymerized polymer has a cyclic structure on the main chain, and thus is easily amorphized. As a result, the fluororesin has high transparency.

Amorphous fluororesins are broadly classified into two types of a bonding amorphous fluororesin having a reactive functional group capable of bonding to a metal such as a carboxyl group, and a non-bonding amorphous fluororesin having a functional group that is hardly bonded to a metal such as a perfluoroalkyl group. The bonding amorphous fluororesin is used for a portion covering a surface of a base, on which a LED chip is mounted, and the LED chip, so that it is possible to improve the bondability between the base or the like and a fluororesin. In the present invention, the term “bonding” includes the meaning of having affinity with an interface of a metal or the like. Similarly, the term “non-bonding” includes the meaning of having non-affinity with an interface of a metal or the like, or having extremely low affinity

Meanwhile, it has been reported in Patent Document 1 and Non-Patent Document 3 above that, in the case where a bonding amorphous fluororesin having a reactive functional group in which a terminal functional group is bondable to a metal is used for a portion covering a pad electrode of a nitride semiconductor ultraviolet light emitting element that emits deep ultraviolet light having a light emission center wavelength of 300 nm or less, the electrical characteristics of the ultraviolet light emitting element are deteriorated when an ultraviolet light emission operation is performed by applying a forward voltage between metal electrode wirings connected to a p-electrode and an n-electrode, respectively, of the ultraviolet light emitting element. Specifically, it has been confirmed that a resistant leakage current path is formed between the p-electrode and the n-electrode of the ultraviolet light emitting element. According to Patent Document 1 above, it is considered that, when the amorphous fluororesin is a bonding amorphous fluororesin, a reactive terminal functional group in the bonding amorphous fluororesin irradiated with high-energy deep ultraviolet light is separated and radicalized due to a photochemical reaction, and coordinate-bonded to metal atoms that form a pad electrode, so that the metal atoms are separated from the pad electrode. Furthermore, it is considered that an electric field is applied between pad electrodes during the light emission operation, and as a result, the metal atoms migrate to form a resistant leakage current path, so that a short-circuit occurs between the p-electrode and the n-electrode of the ultraviolet light emitting element.

Furthermore, it is reported in Non-Patent Document 3 above that, in the case where a bonding amorphous fluororesin is used and a stress by the light emission operation of deep ultraviolet light is continuously applied, the decomposition of the amorphous fluororesin is caused by a photochemical reaction, and air bubbles are generated between an amorphous fluororesin covering a metal electrode wiring on the base side and the metal electrode wiring.

In Patent Document 1 and Non-Patent Document 3 above, for a nitride semiconductor ultraviolet light emitting element that emits deep ultraviolet light, use of the non-bonding fluororesin is recommended in order to avoid the short circuit between the p-electrode and the n-electrode of the ultraviolet light emitting element caused by the photochemical reaction and the generation of the air bubbles between the amorphous fluororesin and the metal electrode wiring.

However, as described above, the non-bonding amorphous fluororesin is hardly bonded to a metal, and is further hardly bonded to the rear surface and side surface of the sapphire substrate that is in direct contact with the non-bonding amorphous fluororesin during flip-chip mounting. That is, bonding provided by van der Waals force at an interface between the non-bonding amorphous fluororesin and the rear surface and side surface of the sapphire substrate is weak, so that when a repulsive force greater than the van der Waals force is generated at the interface by any factor, a part of the amorphous fluororesin is peeled off from the rear surface or side surface of the sapphire substrate, and it cannot deny the possibility of a void to be formed in the peeled portion. If, by any possibility, the void is formed on the rear surface or side surface of the sapphire substrate and a low refractive index gas such as air enters, the transmission of ultraviolet light from the sapphire substrate to the amorphous fluororesin side is inhibited, which may cause decreased extraction efficiency of the ultraviolet light to the outside of the element.

The present invention has been made in view of the above-described problems, and an object thereof is to provide an ultraviolet light emitting device having high quality and high reliability that prevents deterioration in electrical characteristics caused by a photochemical reaction of a non-bonding amorphous fluororesin, decomposition or the like of the amorphous fluororesin, and peeling off of the amorphous fluororesin.

### Means for Solving the Problem

In order to achieve the above object, the present invention provides a nitride semiconductor ultraviolet light emitting device comprising: a base; a nitride semiconductor ultraviolet light emitting element flip-chip mounted on the base; and an amorphous fluororesin that is in direct contact with the nitride semiconductor ultraviolet light emitting element for covering, wherein the nitride semiconductor ultraviolet light emitting element comprises a sapphire substrate, a plurality of AlGaN-based semiconductor layers laminated on a main surface of the sapphire substrate, an n-electrode composed of one or a plurality of metal layers, and a p-electrode composed of one or a plurality of metal layers, a terminal functional group of the amorphous fluororesin is a perfluoroalkyl group, and the amorphous fluororesin enters into depressions formed on a side surface of the sapphire substrate.

In the present invention, the AlGaN-based semiconductor is a group-III nitride semiconductor that is based on a ternary (or binary) compound represented by the general formula: AlₓGa₁₋ₓN (x represents an AlN molar fraction, 0≤x≤1) and has a band gap energy equal to or greater than a band gap energy of GaN (x=0) (about 3.4 eV). As long as conditions regarding the band gap energy are satisfied, the semiconductor may contain a trace amount of In.

In the nitride semiconductor ultraviolet light emitting device having the above feature, first, the non-bonding amorphous fluororesin in which the terminal functional group is the perfluoroalkyl group is used as the resin sealing the nitride semiconductor ultraviolet light emitting element, so that the deterioration in electrical characteristics which is associated with the ultraviolet light emission operation and caused by the photochemical reaction in the case of using the bonding amorphous fluororesin, and the decomposition of the amorphous fluororesin, or the like described above can be prevented.

In the nitride semiconductor ultraviolet light emitting device, the amorphous fluororesin enters into the depressions formed on the side surface of the sapphire substrate, whereby adhesion and a bonding force between the side surface of the sapphire substrate and the amorphous fluororesin can be improved by an anchor effect to prevent the peeling off. By improving the adhesion and the bonding force between the side surface of the sapphire substrate and the amorphous fluororesin to prevent the peeling off, the peeling off of the rear surface of the sapphire substrate from the amorphous fluororesin can also be prevented. Therefore, by preventing the peeling off of the amorphous fluororesin on the side surface and rear surface of the sapphire substrate that is the light (ultraviolet light) emission surface of the nitride semiconductor ultraviolet light emitting element flip-chip mounted, light extraction efficiency can be improved.

Furthermore, in the nitride semiconductor ultraviolet light emitting device having the above feature, it is preferable that a roughened surface band formed by intermittently or continuously connecting the depressions is formed on the side surface of the sapphire substrate. According to the preferred aspect, it is possible to effectively prevent the peeling off of the amorphous fluororesin by intensively improving the adhesion and the bonding force between the side surface of the sapphire substrate and the amorphous fluororesin in the roughened surface band.

Furthermore, in the nitride semiconductor ultraviolet light emitting device having the above feature, it is preferable that the roughened surface band formed on the side surface of the sapphire substrate extends along a direction having a component parallel to the main surface of the sapphire substrate. According to the preferred aspect, by using the roughened surface band formed when general stealth dicing (registered trademark, hereinafter abbreviated) is performed, the adhesion and the bonding force between the side surface of the sapphire substrate and the amorphous fluororesin can be improved. The stealth dicing is a technique of condensing laser light having a wavelength passing through a substrate in the substrate to cause damage to a surface to be cut, and cutting a wafer. By damaging the region extending along in the direction having the component parallel to the main surface of the substrate, the wafer can be easily cut along the direction parallel to the main surface of the substrate.

Furthermore, in the nitride semiconductor ultraviolet light emitting device having the above feature, it is preferable that a plurality of the roughened surface bands are formed on the side surface of the sapphire substrate. By increasing the number of roughened surface bands to 2 or 3 in the preferred aspect, the place where the amorphous fluororesin enters into the depressions formed on the side surface of the sapphire substrate can be increased to 2 or 3 times, whereby the adhesion and the bonding force between the side surface of the sapphire substrate and the amorphous fluororesin can be improved.

In the nitride semiconductor ultraviolet light emitting device having the above feature, the roughened surface band formed on the side surface of the sapphire substrate may be unevenly distributed near a main surface side of the sapphire substrate. In the aspect, by using the roughened surface bands formed when stealth dicing is performed, in which the cracking or chipping (chipping defect) of the AlGaN-based semiconductor layer is suppressed by improving the accuracy of the cutting position on the main surface of the sapphire substrate on which the AlGaN-based semiconductor layer is formed, the adhesion and the bonding force between the side surface of the sapphire substrate and the amorphous fluororesin can be improved.

In the nitride semiconductor ultraviolet light emitting device having the above feature, the roughened surface bands formed on the side surface of the sapphire substrate may be unevenly distributed near the opposite side of the main surface of the sapphire substrate. In the aspect, by using the roughened surface bands formed when performing the stealth dicing, in which the heat of the condensed laser light hardly affects the AlGaN-based semiconductor layer formed on the main surface of the sapphire substrate, the adhesion and the bonding force between the side surface of the sapphire substrate and the amorphous fluororesin can be improved.

Furthermore, in the aspect, the roughened surface bands are unevenly distributed near the opposite side of the main surface of the sapphire substrate (that is, the rear surface side), and a strong anchor effect can be exerted near the rear surface of the sapphire substrate. Therefore, the peeling off of the amorphous fluororesin on the rear surface of the sapphire substrate, that is the main emission surface of light (ultraviolet light) in the flip-chip mounted nitride semiconductor ultraviolet light emitting element, can be effectively prevented.

In the nitride semiconductor ultraviolet light emitting device having the above feature, the roughened surface bands formed on the side surface of the sapphire substrate may be uniformly distributed in a direction perpendicular to the main surface of the sapphire substrate. In the aspect, by using the roughened surface bands formed when the stealth dicing, in which the wafer can be uniformly cut in the direction perpendicular to the main surface of the sapphire substrate, is performed, the adhesion and the bonding force between the side surface of the sapphire substrate and the amorphous fluororesin can be improved.

Furthermore, in the nitride semiconductor ultraviolet light emitting device having the above feature, it is preferable that, when a thickness of the sapphire substrate is X μm, the number of the roughened surface bands formed on the side surface of the sapphire substrate is X/200 or more. According to the preferred aspect, by using the roughened surface bands formed at a density required for certainly cutting the wafer along the surface to be cut to some degree by stealth dicing, the adhesion and the bonding force between the side surface of the sapphire substrate and the amorphous fluororesin can be improved.

Furthermore, in the nitride semiconductor ultraviolet light emitting device having the above feature, it is preferable that, when a thickness of the sapphire substrate is X μm, the number of the roughened surface bands formed on the side surface of the sapphire substrate is X/150 or more. According to the preferred aspect, by using the roughened surface bands formed at a density required for performing extremely good stealth dicing, in which the occurrence rate of defects such as chipping defects is lower than 1%, the adhesion and the bonding force between the side surface of the sapphire substrate and the amorphous fluororesin can be improved.

The present invention further provides a method for manufacturing the nitride semiconductor ultraviolet light emitting device having the above feature, the method comprising: a first step of making laser light having a wavelength passing through the sapphire substrate incident from an opposite side of a main surface of the sapphire substrate, and condensing light in the sapphire substrate to cause damage to a surface to be cut in the sapphire substrate; a second step of cutting the sapphire substrate at the surface to be cut to obtain a side surface of the sapphire substrate from which the depressions are exposed; a third step of applying a coating solution obtained by dissolving the amorphous fluororesin in a predetermined solvent so as to coat an exposed surface of each of the nitride semiconductor ultraviolet light emitting element and the base with the coating solution to fill a gap part between the nitride semiconductor ultraviolet light emitting element and the base; and a fourth step of evaporating the solvent to form a layer made of an amorphous fluororesin covering the exposed surface of each of the nitride semiconductor ultraviolet light emitting element and the base, filling the gap part between the nitride semiconductor ultraviolet light emitting element and the base, and entering into the depressions formed on the side surface of the sapphire substrate.

According to the method for manufacturing the nitride semiconductor ultraviolet light emitting device having the above feature, by performing the stealth dicing, the nitride semiconductor ultraviolet light emitting device is manufactured, in which the amorphous fluororesin is made to enter into the depressions formed on the side surface of the sapphire substrate, and the adhesion and the bonding force between the side surface of the sapphire substrate and the amorphous fluororesin are improved by the anchor effect to prevent the peeling off. Therefore, it is possible to manufacture the nitride semiconductor ultraviolet light emitting device preventing the peeling off of the amorphous fluororesin by simply subjecting the wafer required for the mass production of the chips to the stealth dicing, without separately requiring the step of forming the depressions on the side surface of the sapphire substrate.

### Effect of the Invention

The nitride semiconductor ultraviolet light emitting device having the above feature can provide an ultraviolet light emitting device having high quality and high reliability that prevents deterioration in electrical characteristics caused by a photochemical reaction of a non-bonding amorphous fluororesin, decomposition or the like of the amorphous fluororesin, and peeling off of the amorphous fluororesin.

### BRIEF DESCRIPTION OF THE DRAWINGS

FIG. 1 is a cross-sectional view schematically showing an example of an element structure in one embodiment of a nitride semiconductor ultraviolet light emitting element according to the present invention.

FIG. 2 is a plan view schematically showing the shape of the nitride semiconductor ultraviolet light emitting element shown in FIG. 1 when viewed from a p-electrode and n-electrode side.

FIG. 3 is a cross-sectional view schematically showing one example of a cross-sectional structure in one embodiment of a nitride semiconductor ultraviolet light emitting device according to the present invention.

FIG. 4 is an enlarged cross-sectional view schematically showing a contact portion between a substrate and a sealing resin in the nitride semiconductor ultraviolet light emitting device shown in FIG. 3.

FIGS. 5A and 5B are a plan view and a cross-sectional view schematically showing the shape in plan view and cross-sectional shape of a submount used in the nitride semiconductor ultraviolet light emitting device shown in FIG. 3.

FIGS. 6A and 6B are side views schematically showing a side surface of a substrate.

FIGS. 7A to 7C are photographs showing a part of the side surface of the substrate shown in FIGS. 6A and 6B (near a roughened surface band).

FIG. 8 is a plan view schematically showing the shape of a wafer before a dicing step.

FIGS. 9A to 9C are cross-sectional views schematically showing steps in one example of a method for manufacturing a nitride semiconductor ultraviolet light emitting device according to the present invention.

FIG. 10 is a cross-sectional view schematically showing a step in a cross section perpendicular to the cross section shown in FIG. 9B.

FIGS. 11A to 11C are cross-sectional views schematically showing steps in one example of a method for manufacturing the nitride semiconductor ultraviolet light emitting device according to the present invention.

FIGS. 12A and 12B are side views schematically showing modified examples in which depressions and roughened surface bands are formed on the side surface of a substrate.

FIGS. 13A to 13C are side views schematically showing modified examples in which depressions and roughened surface bands are formed on the side surface of a substrate.

FIGS. 14A and 14B are side views schematically showing modified examples in which depressions are formed on the side surface of a substrate.

### DESCRIPTION OF EMBODIMENT

Embodiments of a nitride semiconductor ultraviolet light emitting device and a method for manufacturing the same according to the present invention will be described with reference to the drawings. In the drawings used in the following descriptions, the substance of the invention is schematically shown while the principal part is partially emphasized for easy understanding of the descriptions, and therefore the dimensional ratio of each part is not always identical to that of each of an actual element and a component to be used. Hereinafter, a nitride semiconductor ultraviolet light emitting device according to the present invention is appropriately referred to as “the present light emitting device”. A method for manufacturing the same is referred to as “the present manufacturing method”. A nitride semiconductor ultraviolet light emitting element used in the present light emitting device is referred to as “the present light emitting element”. Furthermore, in the following description, it is assumed that the present light emitting element is a light emitting diode.

### One Example of Element Structure of Present Light Emitting Element

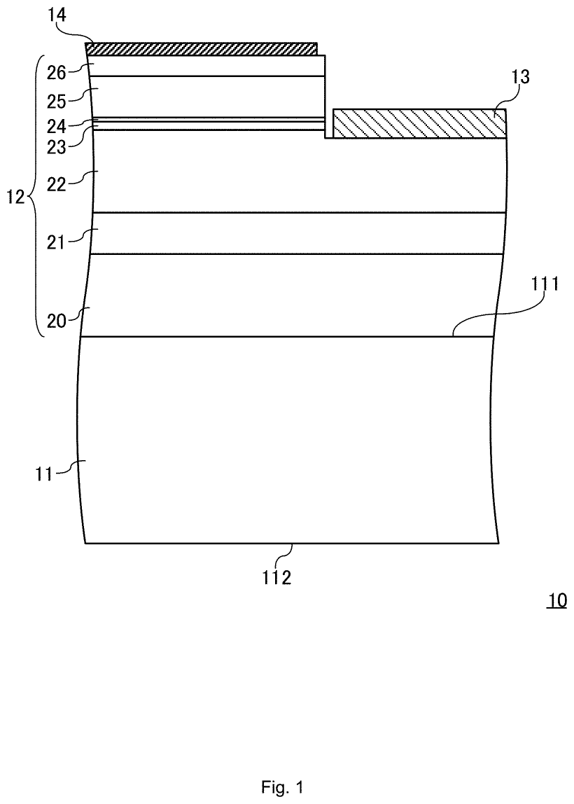

First, the element structure of the present light emitting element 10 will be described. FIG. 1 is a cross-sectional view schematically showing one example of an element structure in one embodiment of a nitride semiconductor ultraviolet light emitting element according to the present invention. As shown in FIG. 1, in the basic element structure of the present light emitting element 10, a semiconductor laminated part 12 including a plurality of AlGaN-based semiconductor layers, an n-electrode 13, and a p-electrode 14 are provided on a main surface 111 of a sapphire substrate 11.

As an example, in the semiconductor laminated part 12, an AlN layer 20, an AlGaN layer 21, an n-type clad layer 22 made of n-type AlGaN, an active layer 23, an electron blocking layer 24 made of p-type AlGaN, a p-type clad layer 25 made of p-type AlGaN, and a p-type contact layer 26 made of p-type GaN are laminated in order from the sapphire substrate 11 side. A light emitting diode structure is formed by from the n-type clad layer 22 to the p-type contact layer 26. The sapphire substrate 11, the AlN layer 20, and the AlGaN layer 21 function as a template for forming the light emitting diode structure thereon. The active layer 23, the electron blocking layer 24, the p-type clad layer 25, and the p-type contact layer 26 located above the n-type clad layer 22 are partially removed by reactive ion etching or the like until a part of the surface of the n-type clad layer 22 is exposed. The semiconductor layer from the active layer 23 to the p-type contact layer 26 located above the exposed surface of the n-type clad layer 22 after the removal is conveniently referred to as a “mesa portion”. As an example, the active layer 23 has a single-layer quantum well structure including an n-type AlGaN barrier layer and an AlGaN or GaN well layer. The active layer 23 may have a double-hetero junction structure sandwiched between n-type and p-type AlGaN layers having a high AlN molar fraction as a lower layer and an upper layer. The active layer 23 may have a multiple quantum well structure provided by the multi-layering of the single-layer quantum well structure.

Each AlGaN layer is formed by a well-known epitaxial growth method such as a metalorganic vapor phase epitaxy (MOVPE) method or a molecular beam epitaxy (MBE) method. For example, Si is used as a donor impurity of an n-type layer. For example, Mg is used as an acceptor impurity of a p-type layer.

For example, an n-electrode 13 made of Ti/Al/Ti/Au is formed on the exposed surface of the n-type clad layer 22. For example, a p-electrode 14 made of Ni/Au is formed on the surface of the p-type contact layer 26. The number and material of metal layers constituting the n-electrode 13 and the p-electrode 14 are not limited to the above-exemplified number and material of the layers.

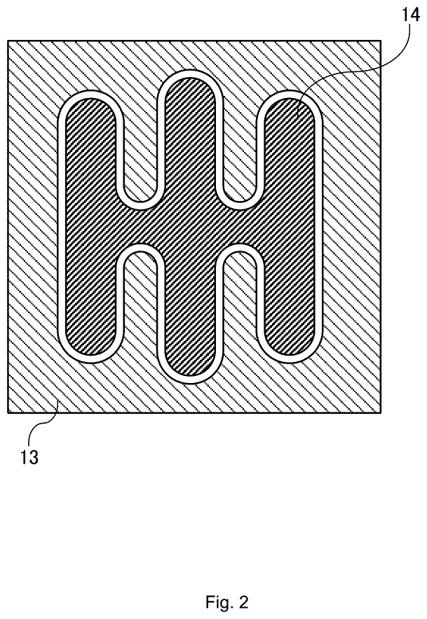

FIG. 2 is a plan view schematically showing the shape of the present light emitting element 10 shown in FIG. 1 when viewed from a p-electrode 14 and n-electrode 13 side. As shown in FIG. 2, in the present embodiment, a configuration example is assumed, in which the shape of the light emitting element 10 in plan view is square, the mesa portion having an upper surface where the p-electrode 14 is formed is positioned at the center, and the exposed surface of the n-type clad layer 22 having an upper surface where the n-electrode 13 is formed surrounds the mesa portion. The shape of the present light emitting element 10 in plan view, the shape of the mesa portion in plan view, the shape and formation position of the n-electrode 13, and the shape and formation position of the p-electrode 14 are not limited to the shapes and formation positions exemplified in FIG. 2.

Details will be described in the following [One Example of Configuration of Present Light Emitting Device], but in the present light emitting device including the present light emitting element 10, depressions are formed on the side surface of the sapphire substrate 11 and an amorphous fluororesin that is a sealing resin enters into the depressions. Therefore, the semiconductor laminated part 12, the n-electrode 13, and the p-electrode 14 formed on the main surface 111 side of the sapphire substrate 11 are not limited to the configurations and structures exemplified above, and various known configurations and structures may be employed. The present light emitting element 10 may include elements other than the semiconductor laminated part 12, the n-electrode 13, and the p-electrode 14, for example, an insulating protective film or the like. Accordingly, the detailed descriptions of the film thicknesses or the like of each of the AlGaN layers 20 to 26 and each of the electrodes 13 and 14 will be omitted. The AlN molar fraction of each of the AlGaN layers 21 to 25 is appropriately set such that the present light emitting element 10 has a light emission center wavelength of about 350 nm or less, and light is emitted through the sapphire substrate 11.

### One Example of Configuration of Present Light Emitting Device

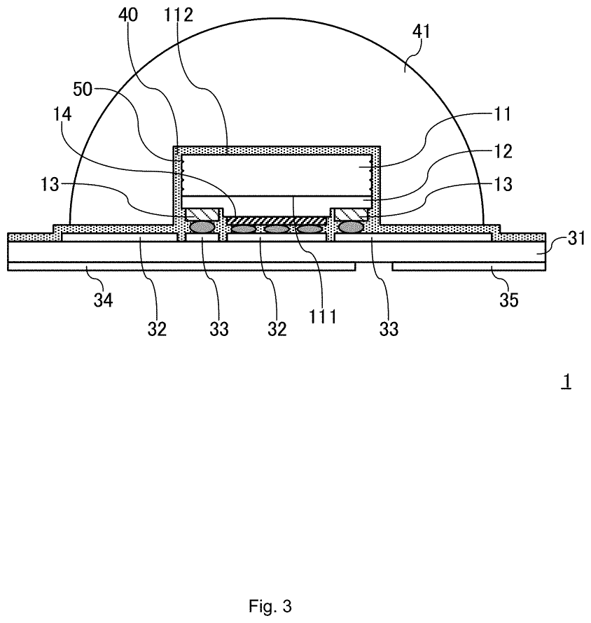

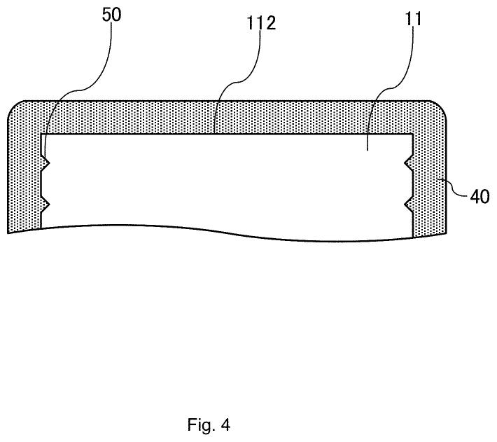

Next, the present light emitting device 1 obtained by placing the present light emitting element 10 on the submount 30 that is a base for flip-chip mounting by a flip-chip mounting method will be described with reference to FIGS. 3, 4, 5A and 5B. FIG. 3 is a cross-sectional view schematically showing the schematic cross-sectional structure of one configuration example of the present light emitting device 1. FIG. 4 is an enlarged sectional view schematically showing a contact portion between the substrate 11 and a sealing resin 40 of the present light emitting device 1 shown in FIG. 3. In FIGS. 3 and 4, the light emitting device 10 is illustrated with the main surface 111 side of the sapphire substrate 11 facing downward, and with a rear surface 112 side that is an opposite surface of the main surface 111 facing upward. In the following description with reference to FIGS. 3 and 4, the upward direction is a direction toward the present light emitting element 10 with reference to the placement surface of the submount 30.

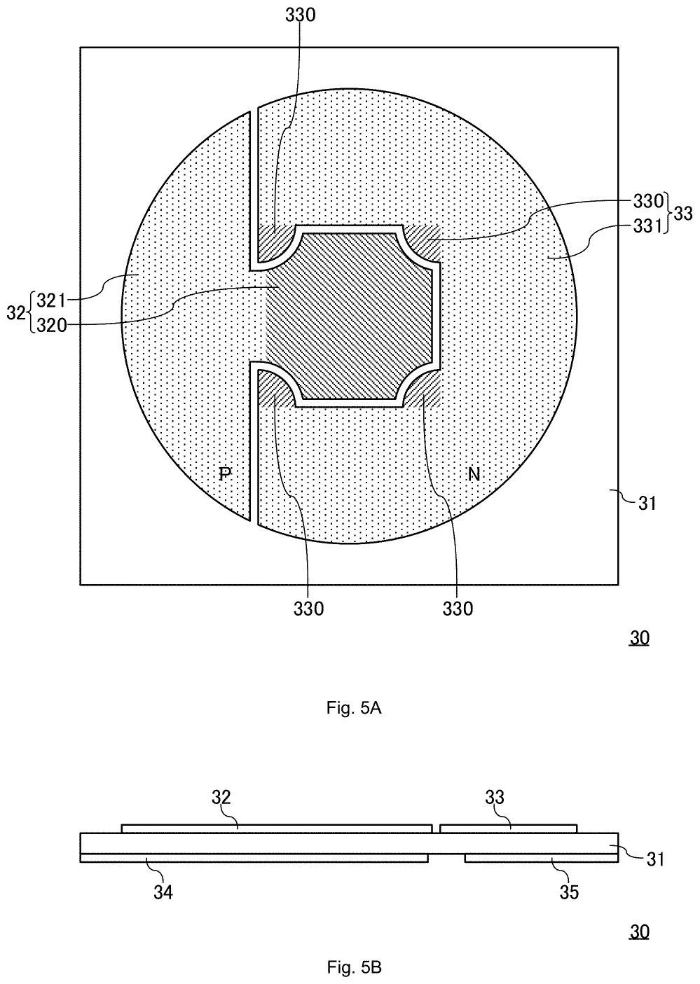

FIG. 5A is a plan view showing the plane shape of the submount 30. FIG. 5B is a cross-sectional view showing the shape of a cross-section which passes through the center of the submount 30 in the plan view (FIG. 5A) and is vertical to the surface of the submount 30. The length of a side of the submount 30 is not limited to a particular value as long as there is room to form a sealing resin around the present light emitting element 10 mounted on the submount 30. As one example, the length of a side of the submount 30 that has a square plane shape, is preferably about 1.5 to 2 times or more greater than the chip size (the length of a side) of the present light emitting element 10 to be mounted, that has also a square plane shape. The plane shape of the submount 30 is not limited to a square shape.

The submount 30 includes a plate-like base material 31 made of an insulating material such as an insulating ceramic. The submount 30 is configured such that a first metal electrode wiring 32 on the anode side and a second metal electrode wiring 33 on the cathode are each formed on the surface side of the base material 31, and lead terminals 34 and 35 are formed on the rear surface side of the base material 31. The first and second metal electrode wirings 32 and 33 on the surface side of the base material 31 are respectively connected to the lead terminals 34 and 35 on the rear surface side of the base material 31 via penetration electrodes (not shown) provided on the base material 31. When the submount 30 is placed on other wiring boards or the like, metals wirings on the wiring boards are electrically connected to the lead terminals 34 and 35. The lead terminals 34 and 35 cover substantially the entire rear surface of the base material 31 to function as a heat sink.

As shown in FIGS. 5A and 5B, the first and second metal electrode wirings 32 and 33 are formed on the center portion of the base material 31 where the present light emitting element 10 is mounted and a surrounding portion thereof. The first and second metal electrode wirings 32 and 33 are disposed so as to be spaced apart from each other, and are electrically separated from each other. The first metal electrode wiring 32 includes a first electrode pad 320 and a first wiring part 321 connected to the first electrode pad 320. The second metal electrode wiring 33 includes four second electrode pads 330 and a second wiring part 331 connected to the second electrode pads 330. The first electrode pad 320 has a plane shape slightly larger than the plane shape of the p-electrode 14 of the present light emitting element 10, and is located at the center of the central portion of the base material 31. In the case where the present light emitting element 10 is disposed such that the p-electrode 14 of the present light emitting element 10 opposes the first electrode pad 320, the plane shape, number, and arrangement of the second electrode pads 330 are set so that the n-electrode 13 opposes the second electrode pad 330. In FIG. 5A, the first electrode pad 320 and the second electrode pad 330 are hatched. The plane shapes of the first and second metal electrode wirings 32 and 33 are not limited to the shapes shown in FIG. 5A, and can be variously modified as long as the first and second metal electrode wirings 32 and 33 have a plane shape such that the p-electrode 14 can oppose the first electrode pad 320 and the n-electrode 13 can oppose the second electrode pads 330.

In the present embodiment, the base material 31 of the submount 30 is composed of an insulating material such as aluminum nitride (AlN) that is not deteriorated by being exposed to ultraviolet light. While the base material 31 is preferably composed of AlN in view of heat dissipation, the base material 31 may be composed of silicon carbide (SiC), silicon nitride (SiN), or boron nitride (BN), or may be ceramics such as alumina (Al₂O₃). The base material 31 may be composed of not only a solid insulating material of the insulating material but also a sintered body obtained by tightly bonding particles of the insulating material using silica glass as a binder. Furthermore, the base material 31 may be composed of a diamond-like carbon (DLC) thin film, an industrial diamond thin film, or the like.

In the case of the configuration in which the lead terminals 34 and 35 are not provided on the rear surface side of the base material 31 in the submount 30, the base material 31 is composed of not only the insulating material, and may have a laminated structure of a metal film (for example, Cu or Al) and an insulating layer composed of the above insulating material.

As an example, the first and second metal electrode wirings 32 and 33 include a thick copper-plated film and a single or multi-layer surface metal film that covers the surface (the upper surface and the side wall surface) of the thick plated film. The outermost layer of the surface metal film is composed of a metal having ionization tendency smaller than that of copper constituting the thick plated film (for example, gold (Au), platinum group metals (Ru, Rh, Pd, Os, Ir, Pt, or two or more alloys thereof), or alloys of gold and platinum group metals).

The present light emitting element 10 is placed and fixed on the central portion of the base material 31 in the following state. The n-electrode 13 and the p-electrode 14 face downward. The p-electrode 14 and the first electrode pad 320 face each other, and are electrically and physically connected to each other via gold bumps or the like (bonding materials). The four n-electrodes 13 and the four second electrode pads 330 face one another, and are electrically and physically connected to one another via gold bumps or the like. As shown in FIG. 3, the present light emitting element 10 mounted on the submount 30 is sealed with a sealing resin 40. Specifically, the sealing resin 40 is in direct contact with, and seal the upper and side surfaces of the present light emitting device 10 (the rear surface 112 and side surface of the substrate 11, the side surface of the semiconductor laminated part 12, the side surfaces of the n-electrode 13 and p-electrode 14), and the upper surface of the submount 30 (the upper and side surfaces of the first and second metal electrode wirings 32 and 33, the surface of the base material 31 exposed between the first and second metal electrode wirings 32 and 33). Furthermore, the sealing resin 40 is filled in a gap part between the submount 30 and the present light emitting element 10.

In present the light emitting device 1, as shown in FIG. 4, the sealing resin 40 enters into depressions 50 formed on the side surface of the substrate 11. As a result, adhesion and a bonding force between the side surface of the substrate 11 and the sealing resin 40 can be improved by an anchor effect, to prevent the peeling off. By improving the adhesion and the bonding force between the side surface of the substrate 11 and the sealing resin 40 to prevent the peeling off, the peeling off between the rear surface 112 of the substrate 11 and the sealing resin 40 can also be prevented. Therefore, light extraction efficiency can be improved by preventing the peeling off of the sealing resin 40 from the side surface and rear surface 112 of the substrate 11, that is the light (ultraviolet light) emission surface of the present light emitting element 10 flip-chip mounted.

In the present embodiment, as shown in FIG. 3, the upper surface of the sealing resin 40 is, as an example, covered with a light condensing lens 41 made of the same fluorocarbon resin as the sealing resin 40. The lens 41 is not limited to be made of a fluororesin, and may be made of other materials having ultraviolet transparency adaptable to the light emission wavelength of the present light emitting element 10. The lens 41 is preferably made of a material having a small refractive index difference between the material and the sealing resin 40, and a quartz glass lens may be used. The lens 41 may be, in addition to a light condensing lens, a lens that diffuses light depending on intended use, and the lens 41 is not necessarily provided.

In the present embodiment, as the sealing resin 40, a non-bonding amorphous fluororesin having excellent heat resistance, ultraviolet resistance, and ultraviolet transparency is used. As described above, examples of the amorphous fluororesin include one with a fluororesin of a crystalline polymer copolymerized and made amorphous as a polymer alloy, a copolymer of perfluorodioxole (trade name Teflon AF (registered trademark) manufactured by du Pont) and a cyclopolymerized polymer of perfluorobutenyl vinyl ether (trade name CYTOP (registered trademark) manufactured by Asahi Glass Co., Ltd.). In the present embodiment, as an example, a non-bonding amorphous fluororesin is used, in which a structural unit constituting a polymer or copolymer has a fluorine-containing aliphatic cyclic structure, and a terminal functional group is a perfluoroalkyl group such as CF₃. The perfluoroalkyl group is hardly bonded to a metal or the like. That is, the non-bonding amorphous fluororesin does not have a reactive terminal functional group capable of bonding to a metal. Meanwhile, the bonding amorphous fluororesin has a reactive functional group that can be bonded to a metal as a terminal functional group even if the structural unit constituting the polymer or copolymer has the same fluorine-containing aliphatic cyclic structure, which is different from the non-bonding amorphous fluororesin. The reactive functional group is, as an example, a carboxyl group (COOH) or an ester group (COOR), where R represents an alkyl group.

The structural unit having the fluorine-containing aliphatic cyclic structure is preferably a unit based on a cyclic fluorine-containing monomer (hereinafter, “unit A”) or a unit formed by cyclopolymerization of diene fluorine-containing monomers (hereinafter, “unit B”). The composition and structure of the amorphous fluororesin are not the subject of the invention of the present application, and thus detailed descriptions of the unit A and the unit B will be omitted. For reference, the unit A and the unit B are described in detail in paragraphs [0031] to [0062] of Patent Document 1 by the same applicant as that of the present application.

Examples of commercially available products of the non-bonding amorphous fluororesin include CYTOP (manufactured by Asahi Glass Co., Ltd.) and the like. CYTOP having a CF₃ terminal functional group is a copolymer of the unit B represented by the following Chemical Formula 1.

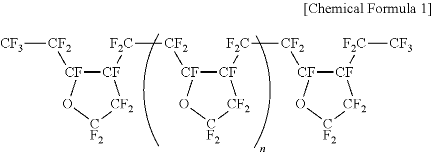

In the present light emitting device 1, such a non-bonding amorphous fluororesin enters into the depressions 50 formed on the side surface of the substrate 11. Thereby, as described above, the adhesion and the bonding force between the side surface of the substrate 11 and the sealing resin 40 are improved by the anchor effect, whereby the peeling off is prevented. The adhesion and the bonding force between the side surface of the substrate 11 and the sealing resin 40 are improved to prevent the peeling off whereby the peeling off of the rear surface 112 of the substrate 11 from the sealing resin 40 is also prevented.

As described above, in the present light emitting device 1, by using the non-bonding amorphous fluororesin as the sealing resin 40, deterioration in electrical characteristics caused by a photochemical reaction and decomposition or the like of the amorphous fluororesin can be prevented. By the anchor effect obtained by the sealing resin 40 entering into the depressions 50 formed on the side surface of the substrate 11, a problem in the case where the non-bonding amorphous fluororesin is used, that is, the peeling off of the amorphous fluororesin from the rear surface 112 and side surface of the substrate 11 can be prevented, whereby a reduction in extraction efficiency of ultraviolet light to the outside of the element can be prevented.

### One Example of Depressions Formed on Side Surface of Substrate

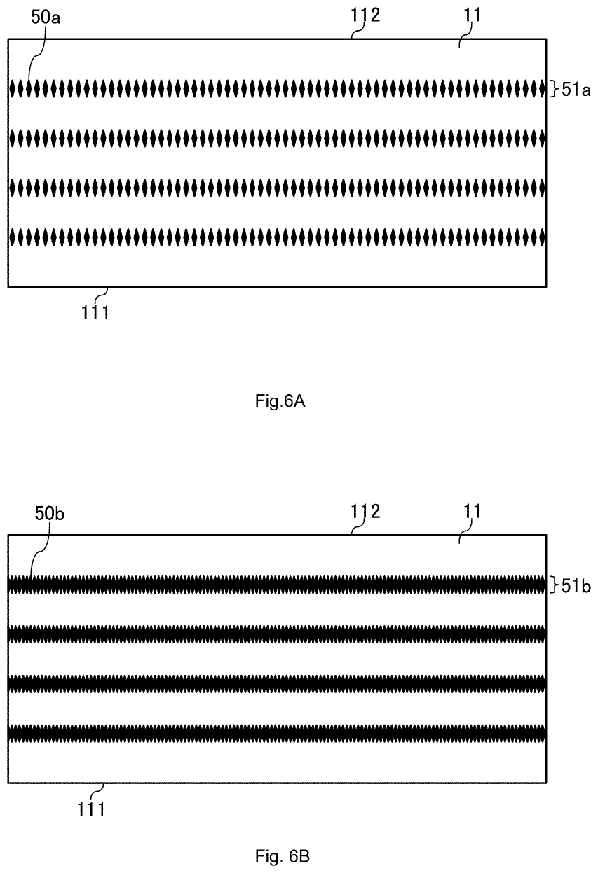

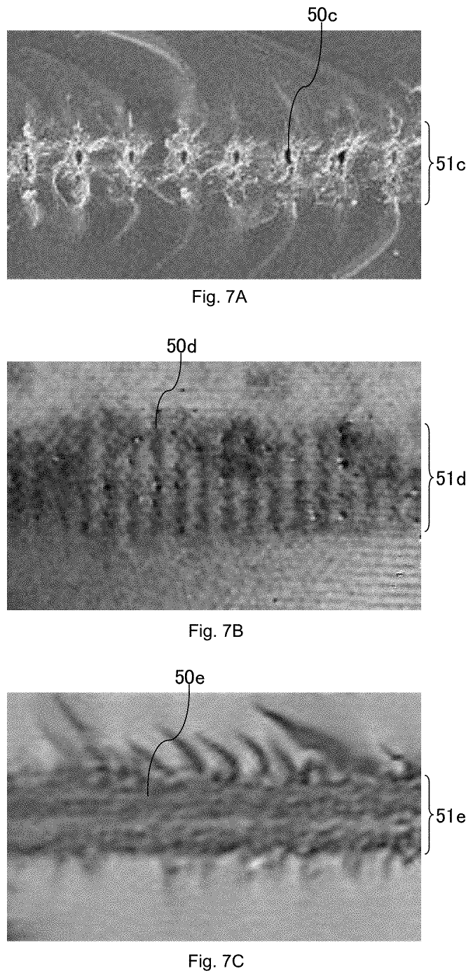

Next, depressions formed on the side surface of the substrate 11 in the present light emitting device 1 will be described with reference to the drawings. FIGS. 6A and 6B are side views schematically showing the side surface of the substrate 11. FIGS. 7A to 7C are photographs showing a part of the side surface of the substrate 11 shown in FIGS. 6A and 6B (the vicinity of roughened surface bands 51a, 51b). The vertical direction in FIGS. 6A, 6B, and 7A to 7C is the same as the vertical direction in FIGS. 3 and 4.

FIGS. 6A and 6B show two different types of depressions 50a and 50b. FIG. 6A exemplifies a case where the plurality of depressions 50a formed on the side surface of the substrate 11 are intermittently connected to form the roughened surface band 51a (in other words, by arranging the adjacent depressions 50a in a row in a separated state, the roughened surface band 51a is formed), and the four roughened surface bands 51a are formed on the side surface of the substrate 11. FIG. 6B exemplifies a case where a plurality of depressions 50b formed on the side surface of the substrate 11 are continuously connected to form the roughened surface band 51b (in other words, the end parts of the adjacent depressions 50b are arranged in a row in a state where the end parts are joined together, to form the roughened surface band 51b), and the four roughened surface bands 51b are formed on the side surface of the substrate 11. The roughened surface bands 51a and 51b exemplified in FIGS. 6A and 6B can also be said to be different only in the distance between the adjacent depressions 50a and 50b.

The roughened surface bands 51c, 51d shown in FIGS. 7A and 7B include intermittently connected depressions 50c, 50d, as in the roughened surface bands 51a of FIG. 6A. However, the depressions 50d in FIG. 7B are thinner than the depressions 50c in FIG. 7A, and the adjacent interval between the depressions 50d is narrower than the adjacent interval between the depressions 50c in FIG. 7A. Roughened surface bands 51e shown in FIG. 7C include depressions 50e continuously connected as in the roughened surface bands 51b of FIG. 6B.

The depressions 50a to 50e as shown in FIGS. 6A, 6B, and 7A to 7C can also be formed by exposing the side surface of the substrate 11 according to a dicing step of cutting the wafer to obtain the present light emitting element 10 (chip), and thereafter subjecting the side surface of the substrate 11 to a blast treatment (for example, spraying particles having a hardness equal to or higher than that of sapphire such as diamond) or the like. However, if the depressions 50a to 50e can be formed simultaneously with the dicing step, an increase in the number of steps can be prevented, which is preferable. Therefore, in the following [Method for Manufacturing Present Light Emitting Device], a method for forming the depressions 50a to 50e on the side surface of the substrate 11 simultaneously with the dicing step will be described.

### Method for Manufacturing Present Light Emitting Device

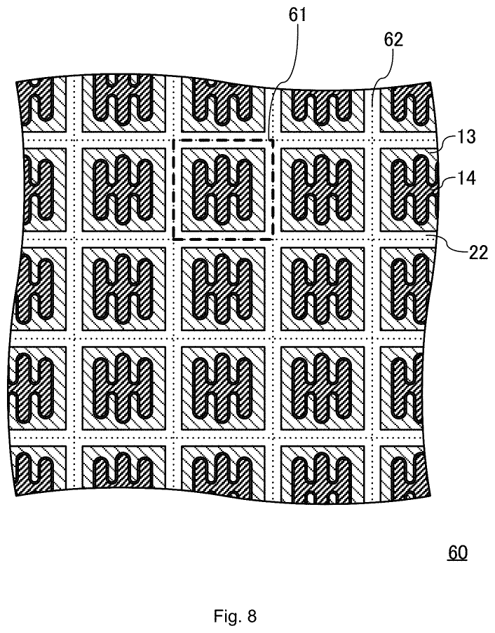

A method for manufacturing the present light emitting device 10 will be described with reference to the drawings. First, on the main surface 111 of the sapphire substrate 11 that is in a wafer state (state before being cut into chips), the semiconductor laminated part 12, the n-electrode 13, the p-electrode 14, and the protective film or the like are formed by a well-known nitride semiconductor manufacturing step. As a result, a wafer 60 as shown in FIG. 8 is obtained. FIG. 8 is a plan view schematically showing the shape of the wafer 60 before the dicing step, and is a plan view when the wafer 60 is viewed from the p-electrode 14 and n-electrode 13 side.

As shown in FIG. 8, in the wafer 60, chip regions 61 to be chips (present light emitting elements 10) after the wafer 60 is cut are arranged in matrix. In the wafer 60, a surface serving as a boundary between the chip regions 61 is a surface to be cut 62 that is a surface to be cut in the dicing step. In the wafer 60 shown in FIG. 8, the outermost surface in the vicinity of the boundary (surface to be cut 62) of the chip regions 61 is an n-type clad layer 22 exposed for forming the n-electrode 13, but the n-type clad layer 22 may be further removed to expose the substrate 11.

In the present manufacturing method, stealth dicing is performed in the dicing step. The stealth dicing is a technique of condensing laser light having a wavelength passing through the substrate 11 in the substrate 11 to cause damage to the surface to be cut 62, and cut the wafer 60.

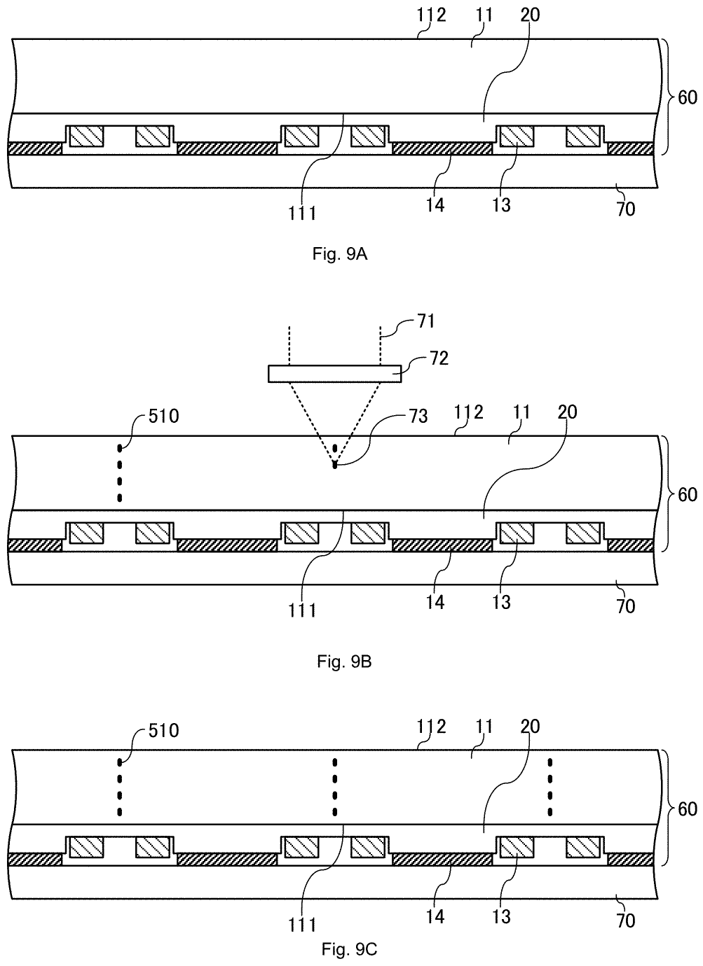

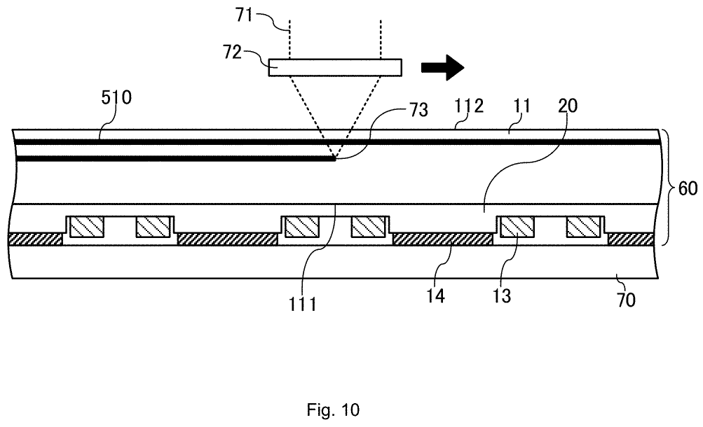

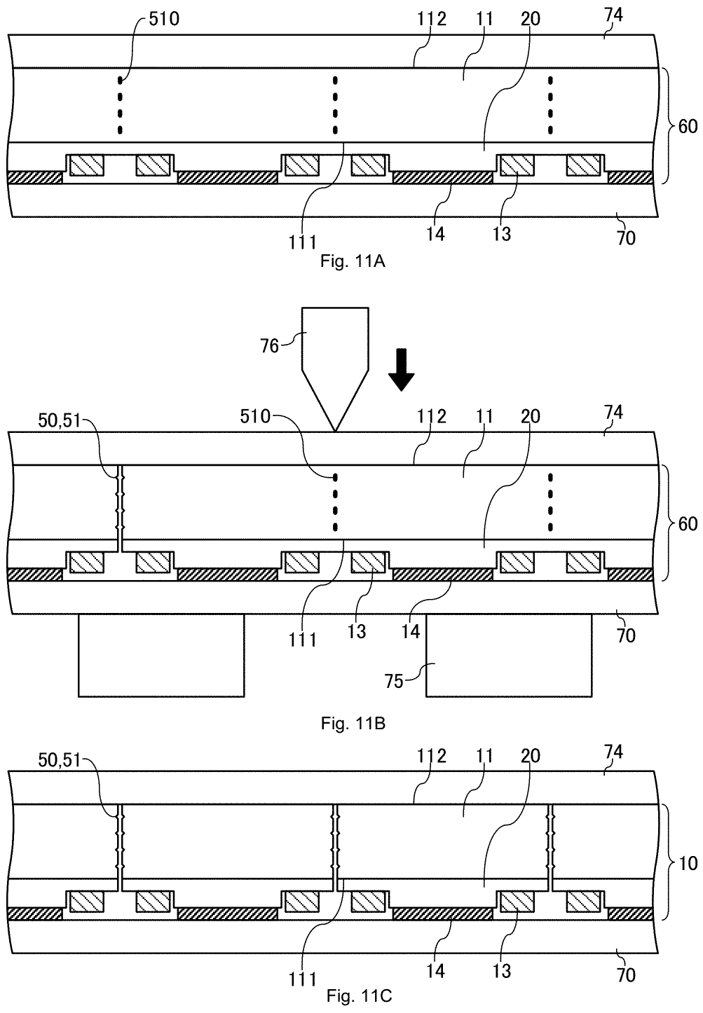

One example of the stealth dicing step is shown in FIGS. 9A to 9C, 10, and 11A to 11C. FIGS. 9A to 9C, 10, and 11A to 11C are cross-sectional views schematically showing steps in one example of the present manufacturing method. In the present manufacturing method, steps are sequentially performed in order of FIG. 9A, FIG. 9B and FIG. 10, FIG. 9C, FIG. 11A, FIG. 11B, and FIG. 11C. FIG. 10 is a cross-sectional view showing the same step as that of FIG. 9B, and shows a cross section perpendicular to FIG. 9B. The vertical direction in FIGS. 9A to 9C, 10, and 11A to 11C is also the same as the vertical direction in FIGS. 3 and 4.

First, as shown in FIG. 9A, the main surface 111 side of the substrate 11 in the wafer 60 (hereinafter simply referred to as “main surface side”) is attached to a first sheet 70.

Next, as shown in FIG. 9B, the rear surface 112 side (hereinafter simply referred to as “rear surface side”) of the substrate 11 in the wafer 60 is irradiated with laser light 71. At this time, a condensing lens 72 is used to condense the laser light 71 entering into the substrate 11 from the rear surface 112 of the substrate 11 onto the surface to be cut 62. For example, the laser light 71 has a wavelength (specifically, for example, 532 nm that is second harmonic of Nd-YAG laser, 355 nm that is third harmonic, or the like) passing through the sapphire substrate 11, and the wafer 60 is irradiated with pulses. When the laser light 71 is condensed in the substrate 11, light absorption occurs in a light condensing region 73, to cause the temperature to locally rise, whereby damage is caused to the light condensing region 73 by melting or expanding or the like. As shown in FIG. 10, by irradiating the main surface 111 of the substrate 11 with the laser light 71 while moving the position of the light condensing region 73 along the direction parallel to the main surface 111 of the substrate 11 (the direction of a black arrow in the drawing), a band-like modified layer 510 (a portion that becomes the roughened surface band 51 after the wafer 60 is cut) is formed. Furthermore, the position of the light condensing region 73 in the direction perpendicular to the main surface 111 of the substrate 11 (the vertical direction in the drawing) is changed, and the main surface 111 of the substrate 11 is irradiated with the laser light 71 while the position of the light condensing region 73 is moved along the direction parallel to the main surface 111 of the substrate 11 again, whereby a plurality of modified layers 510 are formed on the surface to be cut 62 of the substrate 11. The position of the light condensing region 73 can be moved by driving at least one of the wafer 60 and the optical system (the light source of the laser light 71 or the light condensing lens 72 or the like).

When the steps shown in FIGS. 9B and 10 are completed, as shown in FIG. 9C, the modified layer 510 is formed on all the surfaces to be cut 62 (see FIG. 8) in the wafer 60. Next, as shown in FIG. 11A, a second sheet 74 is attached to the rear surface side of the wafer 60 (the rear surface of the substrate 11). As shown in FIG. 11B, blocks 75 are disposed at positions avoiding the surface to be cut 62 on the main surface side of the wafer 60, and a blade 76 is pressed to a position immediately above the surface to be cut 62 on the rear surface side of the wafer 60 to cut the wafer 60. At this time, the damaged modified layer 510 is formed on the surface to be cut 62 of the wafer 60 (substrate 11), and easily cut, whereby the wafer 60 is cut along the surface to be cut 62. On the side surface of the substrate 11 obtained by cutting the wafer 60, the depressions 50 and the roughened surface bands 51 are exposed by cutting the modified layer 510. The shapes of the depressions 50 and the roughened surface bands 51 exposed on the side surface of the substrate 11 are determined according to the characteristics (intensity, pulse width, pulse interval, or the like) of the laser light incident on the substrate 11 in order to form the modified layer 510 in the steps of FIGS. 9B and 10. For example, as the intensity and pulse width of the laser light are larger, larger depressions 50 can be formed, and as the pulse width and pulse interval of the laser light are smaller, finer depressions 50 can be formed at a higher density.

When the step of FIG. 11B is completed, as shown in FIG. 11C, all chips (present light emitting elements 10) are cut out from the wafer 60. Thereafter, for example, the present light emitting element 10 peeled off from the first sheet 70 and the second sheet 74 and picked up is fixed on the first and second metal electrode wirings 32, 33 of the submount 30 by well-known flip chip mounting. Specifically, the p-electrode 14 and the first metal electrode wiring 32 are physically and electrically connected to each other via a gold bump or the like, and the n-electrode 13 and the second metal electrode wiring 33 are physically and electrically connected to each other via a gold bump or the like (see FIG. 3).

Subsequently, a coating solution obtained by dissolving a non-bonding amorphous fluororesin in a fluorine-containing solvent, preferably an aprotic fluorine-containing solvent is injected onto the submount 30 and the present light emitting element 10 using a Teflon needle having good peelability or the like, and the solvent is then evaporated while gradually heating the coating solution, whereby a sealing resin 40 that is a non-bonding amorphous fluororesin is formed on the upper surface and side surface of the present light emitting element 10 (the rear surface 112 and side surface of the substrate 11, the side surface of the semiconductor laminated part 12, the side surfaces of the n-electrode 13 and p-electrode 14), the upper surface of the submount 30 (the upper and side surfaces of the first and second metal electrode wirings 32 and 33, the surface of the base material 31 exposed between the first and second metal electrode wirings 32 and 33), and the gap part between the submount 30 and the present light emitting element 10 (see FIG. 3). At this time, the sealing resin 40 enters into the depressions 50 formed on the side surface of the substrate 11 (see FIG. 4). When the solvent is evaporated in the step, the solvent is gradually heated from a low-temperature range equal to or lower than the boiling temperature of the solvent (for example, about room temperature) to a high-temperature range equal to or higher than the boiling point of the solvent (for example, about 200° C.) to be evaporated without air bubbles remaining in the sealing resin 40.

Subsequently, a lens 41 made of the same non-bonding amorphous fluororesin as the sealing resin 40 is formed on the upper part of the sealing resin 40 so as to cover the present light emitting element 10 by, for example, injection molding, transfer molding, compression molding, or the like (see FIG. 3). As a mold for each of the above moldings, a metal mold, a silicone resin mold, or a combination thereof can be used.

As described above, in the present manufacturing method, by performing the stealth dicing, the present light emitting device 1 is manufactured, in which the sealing resin 40 that is the amorphous fluororesin is caused to enter into the depressions 50 formed on the side surface of the substrate 11, and the adhesion and the bonding force between the side surface of the substrate 11 and the sealing resin 40 are improved by the anchor effect, to prevent the peeling off. Therefore, by merely subjecting the wafer 60 required for the mass production of the chips to stealth dicing, without separately requiring the step of forming the depressions 50 on the side surface of the substrate 11, the present light emitting device 1 preventing the peeling off of the sealing resin 40 can be manufactured.

After the formation of the sealing resin 40, in a temperature range that is lower than a temperature (about 350° C.) at which the decomposition of the non-bonding amorphous fluororesin starts, for example, 150° C. to 300° C., more preferably 200° C. to 300° C., the sealing resin 40 may be heated and softened to press the sealing resin 40 on the side surface (or the side surface and the upper surface) of the present light emitting element 10 toward the present light emitting element 10. As a result, the sealing resin 40 is densely filled in the depressions 50 in a compressed state. As a result, the sealing resin 40 filled in the depressions 50 is less likely to come off, and reliably functions as an anchor. The heat treatment and pressing treatment of the sealing resin 40 may be performed simultaneously with the formation of the lens 41. Alternatively, only the heat treatment may be performed first, and the pressing treatment may be performed simultaneously with the formation of the lens 41. Only one of the heat treatment and the pressing treatment may be performed.

### Another Embodiments

Modified examples of the above embodiment will be described below.

<1>In the above embodiment, the case where the p-electrode 14 and the first metal electrode wiring 32 are connected to each other via the gold bump, and the n-electrode 13 and the second metal electrode wiring 33 are connected to each other via the gold bump has been described as one aspect of flip-chip mounting the present light emitting element 10 on the submount 30. However, for example, when the upper surfaces of the p-electrode 14 and n-electrode 13 are formed with uniform height such that the upper surfaces thereof are flush with each other, the p-electrode 14 and the first metal electrode wiring 32 may be physically and electrically connected to each other via a solder material (bonding material) and the n-electrode 13 and the second metal electrode wiring 33 may be physically and electrically connected to each other via a solder material (bonding material), by a well-known soldering method such as a reflow method. As a method for making the height uniform such that the upper surfaces of the p-electrode 14 and n-electrode 13 are flush with each other, for example, it is considered a method for forming a p-side plated electrode that is electrically connected to the p-electrode 14 and that covers the upper and side surfaces of the mesa portion via an insulating protective layer, and forming an n-side plated electrode that is electrically connected to the n-electrode 13 while being separated from the p-side plated electrode with the same height as that of the p-side plated electrode by an electrolytic plating method or the like. For the details of the plated electrode, reference is made to the description of International Application (PCT/JP2015/060588) or the like.

<2>In the above embodiment, the present light emitting device 1 in which one light emitting element 10 is placed on the submount 30 has been described. However, the present light emitting device 1 may be configured such that a plurality of light emitting elements 10 is placed on a base such as a submount or a printed board. In this case, the plurality of light emitting elements 10 may be sealed collectively with the sealing resin 40, or may be individually sealed one by one. In this case, for example, a resin dam surrounding one or a plurality of light emitting elements 1 as a unit to be sealed is formed on the surface of the base. In a region surrounded by the resin dam, for example, the sealing resin 40 is formed as described in the embodiment. The base on which the present light emitting element 10 is placed is not limited to the submount and the printed board.

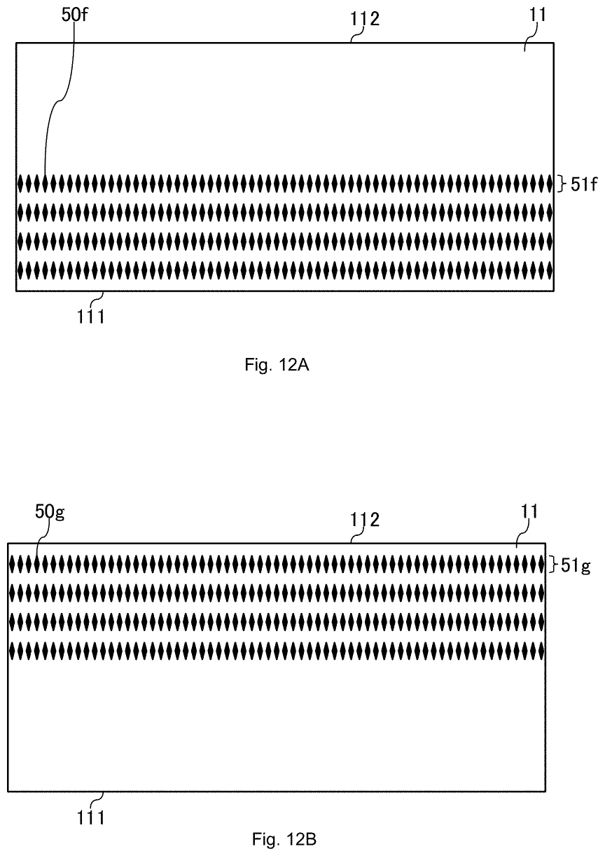

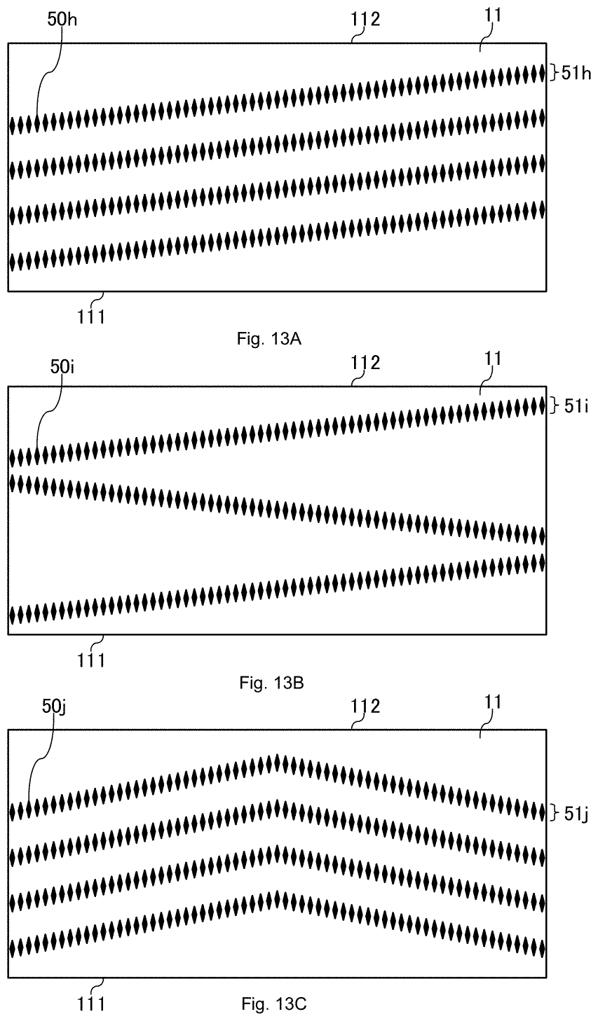

The present light emitting device 1 in which one light emitting element 10 is placed on the submount 30 may be manufactured as follows. Even when one light emitting element 10 is mounted on the submount 30, the first and second metal electrode wirings 32 and 33 of the plurality of submounts 30 are formed on the surface side of one base material 31, and the lead terminals 34 and 35 of the plurality of submounts 30 are formed on the rear surface side of one base material 31. Each of the plurality of light emitting elements 10 is flip-chip mounted on the plurality of submounts 30 in the submount plate on which the plurality of the submounts 30 are disposed in a matrix form. After the sealing resin 40, or the sealing resin 40 and the lens 41 are formed on the plurality of light emitting elements 10, the submount plate is divided into each of the submounts 30.

<3>In the above embodiment, the case is exemplified, in which the plurality of (four) roughened surface bands 51 parallel to the main surface 111 of the substrate 11 are formed so as to be uniformly dispersed on the side surface of the substrate 11 in a direction perpendicular to the main surface 111 of the substrate 11 (for example, see FIGS. 6A and 6B), but the aspect of the roughened surface bands 51 are not limited to this example. Hereinafter, a modified example of the roughened surface bands 51 will be described with reference to the drawings. FIGS. 12A, 12B and 13A to 13C that are side views schematically showing modified examples of the depressions 50 and the roughened surface bands 51, which will be referred to below show a side view of the substrate 11 that is the same as the side views shown in FIGS. 6A and 6B.

Roughened surface bands 51f shown in FIG. 12A are not uniformly dispersed in the direction perpendicular to the main surface 111 of the substrate 11 as in the above embodiment, but are unevenly distributed near the main surface 111 side of the substrate 11. On the other hand, roughened surface bands 51g shown in FIG. 12B are unevenly distributed near the side opposite to the main surface 111 of the substrate 11 (that is, on the rear surface 112 side of the substrate 11). As described above, the roughened surface bands 51 are formed at a position where the modified layer 510 of the wafer 60 is formed. On the main surface 111 of the substrate 11, the semiconductor laminated part 12 is formed (see FIGS. 9A to 9C, 10, and 11A to 11C).

As shown in FIG. 12A, when the roughened surface bands 51f are unevenly distributed near the main surface 111 side of the substrate 11, the modified layer 510 of the wafer 60 is unevenly formed near the main surface 111 side of the substrate 11, whereby stealth dicing is performed, in which the precision of a cutting position in the vicinity of the main surface 111 of the substrate 11 is improved to suppress the cracking or chipping (chipping defect) of the semiconductor laminated part 12. On the other hand, as shown in FIG. 12B, when the roughened surface bands 51g are unevenly distributed near the rear surface 112 of the substrate 11, whereby the modified layer 510 of the wafer 60 is unevenly formed near the rear surface 112 side of the substrate 11, stealth dicing is performed, in which the heat of the condensed laser light 71 hardly affects the semiconductor laminated part 12. When the roughened surface bands 51a and 51b are uniformly distributed in the direction perpendicular to the main surface 111 of the substrate 11 as shown in FIGS. 6A and 6B, the modified layer 510 of the wafer 60 is formed so as to be uniformly distributed in the direction perpendicular to the main surface 111 of the substrate 11, whereby the stealth dicing is performed, in which the wafer 60 can be uniformly cut in the direction.

As shown in FIG. 12B, when the roughened surface bands 51g are unevenly distributed near the rear surface 112 side of the substrate 11, a strong anchor effect can be exerted near the rear surface 112 of the substrate 11. Therefore, the peeling off of the sealing resin 40 on the rear surface 112 of the substrate 11, which is the main emission surface of light (ultraviolet light) in the present nitride semiconductor ultraviolet light emitting element 10 flip-chip mounted can be effectively prevented.

The roughened surface bands 51h to 51j shown in FIGS. 13A to 13C are not parallel to the main surface 111 of the substrate 11. In particular, all the roughened surface bands 51h shown in FIG. 13A are parallel, but a part of the roughened surface bands 51i shown in FIG. 13B are not parallel, and the roughened surface bands 51j shown in FIG. 13C are bent. However, each of the roughened surface bands 51h to 51j extends in a direction having a component parallel to the main surface 111 of the substrate 11. Therefore, even when such roughened surface bands 51h to 51j are formed, the modified layer 510 extending in the direction having a component parallel to the main surface 111 of the substrate 11 is formed on the wafer 60, whereby the wafer 60 can be easily cut along the direction parallel to the main surface 111 of the substrate 11.

<4>In the above embodiment, the stealth dicing can be performed even if the number of the modified layers 510 to be formed on the wafer 60 is set to 1, and an effect of improving the adhesion and the bonding force between the side surface of the substrate 11 and the sealing resin 40 can also be obtained. However, in the present light emitting device 1, the thickness of the substrate 11 may be increased (for example, about 400 μm) in order to improve the extraction efficiency of light (ultraviolet light) (see, for example, International Publication No. 2015/111134). In this case, if the number of the modified layers 510 is insufficient with respect to the thickness of the substrate 11, it may be difficult to cut the wafer 60 along the surface to be cut 62.

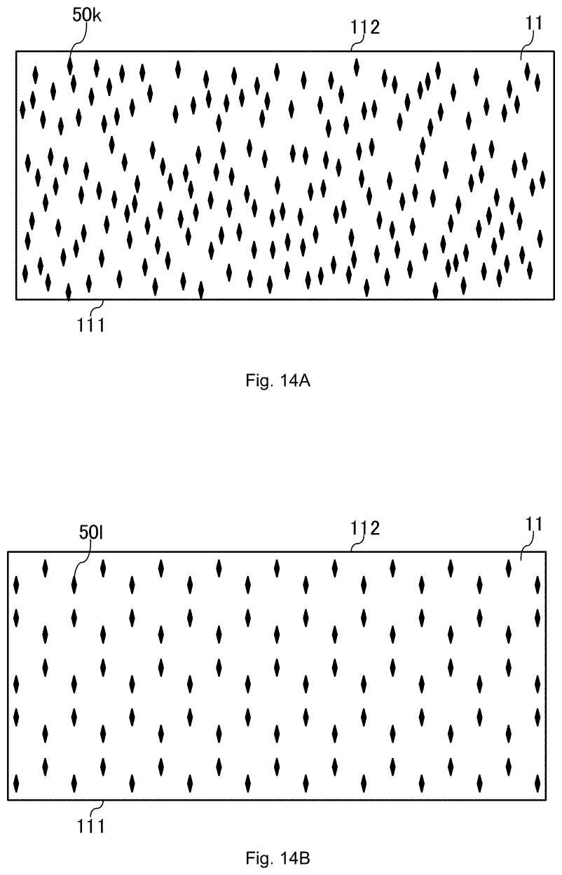

In this respect, if the number of the modified layers 510 (the number of the roughened surface bands 51) is set to X/200 or more when the thickness of the substrate 11 is X μm, the wafer 60 can be certainly cut to some degree by the stealth dicing along the surface to be cut 62. Furthermore, if the number of the modified layers 510 (the number of the roughened surface bands 51) is set to X/150 or more, extremely good stealth dicing can be performed, in which the incidence rate of defects such as chipping defects is lower than 1%.

<5>In the above embodiment, the case where the roughened surface bands 51 are formed by connecting the depressions 50 on the side surface of the substrate 11 in the present light emitting element 10 is exemplified, but as long as the depressions 50 are formed on the side surface of the substrate 11, the roughened surface bands 51 may not necessarily be formed. One example of this case will be described with reference to the drawings. FIGS. 14A and 14B are side views schematically showing a modified example of the depressions formed on the side surface of the substrate 11. FIGS. 14 A and 14B show a side surface of the substrate 11 similar to the side view shown in FIGS. 6A and 6B.

The depressions 50k shown in FIG. 14A are formed so as to be randomly dispersed with respect to the side surface of the substrate 11. Such depressions 50k can be formed by randomly moving the position of the light condensing region 73 of the laser light 71 when performing the stealth dicing (see FIGS. 9B and 10), but the depressions 50k can be formed by cutting the wafer 60 by a known or new dicing technique, and thereafter subjecting the side surface of the substrate 11 to a blasting treatment or the like. The depressions 501 shown in FIG. 14B are formed so as to be regularly dispersed with respect to the side surface of the substrate 11. Such depressions 501 can be formed, for example, by regularly moving the position of the light condensing region 73 of the laser light 71 when performing the stealth dicing.

Even when such depressions 50k and 501 are formed, the adhesion and the bonding force between the side surface of the substrate 11 and the sealing resin 40 can be improved by the anchor effect to prevent the peeling off, and the stealth dicing is also possible.

<6>In the above embodiment, the lens 41 made of the amorphous fluororesin having the same non-bonding property as that of the sealing resin 40 is formed on the sealing resin 40, but other resin portion or the like may be formed without forming the lens 41. For example, the base used in the flip-chip mounting is not the submount 30 as illustrated in FIG. 5, but when a side wall surrounding the present light emitting element 10, which is higher than the upper surface of the present light emitting element 10 after the flip chip mounting, is provided on the outer periphery portion of the base material 31, the solid-like non-bonding amorphous fluororesin may be placed in a space surrounded by the side wall on the sealing resin 40, melted to a high temperature, for example, 250° C. to 300° C., and then gradually cooled to form the second sealing resin layer. If necessary, the lens 41 may be formed on the second sealing resin film.

### INDUSTRIAL APPLICABILITY

The nitride semiconductor ultraviolet light emitting device according to the present invention can be used for the rear surface emission type light emitting diode having a light emission center wavelength of about 350 nm or less.

### DESCRIPTION OF SYMBOLS

1 nitride semiconductor ultraviolet light emitting device

10 nitride semiconductor ultraviolet light emitting element

11 sapphire substrate

111 main surface

112 rear surface

12 semiconductor laminated part (AlGaN-based semiconductor layer)

13 n-electrode

14 p-electrode

20 AlN layer

21 AlGaN layer

22 n-type clad layer

23 active layer

24 electron blocking layer

25 p-type clad layer

26 p contact layer

30 submount (base)

31 base material

32 first metal electrode wiring

320 first electrode pad

321 first wiring part

33 second metal electrode wiring

330 second metal electrode pad

331 second wiring part

34, 35 lead terminal

40 sealing resin (amorphous fluororesin)

41 lens

50, 50a to 50l depression

51, 51a to 51j roughened surface band

510 modified layer

60 wafer

61 chip region

62 surface to be cut

70 first sheet

71 laser light

72 light condensing lens

73 light condensing region

74 second sheet

75 block

76 blade

1. A nitride semiconductor ultraviolet light emitting device comprising:
a base;
a nitride semiconductor ultraviolet light emitting element flip-chip mounted on the base; and
an amorphous fluororesin that is in direct contact with the nitride semiconductor ultraviolet light emitting element for covering,
wherein
the nitride semiconductor ultraviolet light emitting element comprises a sapphire substrate, a plurality of AlGaN-based semiconductor layers laminated on a main surface of the sapphire substrate, an n-electrode composed of one or a plurality of metal layers, and a p-electrode composed of one or a plurality of metal layers,
a terminal functional group of the amorphous fluororesin is a perfluoroalkyl group, and
the amorphous fluororesin enters into depressions formed on a side surface of the sapphire substrate.

2. The nitride semiconductor ultraviolet light emitting device according to claim 1, wherein a roughened surface band formed by intermittently or continuously connecting the depressions is formed on the side surface of the sapphire substrate.

3. The nitride semiconductor ultraviolet light emitting device according to claim 2, wherein the roughened surface band formed on the side surface of the sapphire substrate extends along a direction having a component parallel to the main surface of the sapphire substrate.

4. The nitride semiconductor ultraviolet light emitting device according to claim 3, wherein a plurality of the roughened surface bands are formed on the side surface of the sapphire substrate.

5. The nitride semiconductor ultraviolet light emitting device according to claim 4, wherein the roughened surface band formed on the side surface of the sapphire substrate is unevenly distributed near the main surface side of the sapphire substrate.

6. The nitride semiconductor ultraviolet light emitting device according to claim 4, wherein the roughened surface band formed on the side surface of the sapphire substrate is unevenly distributed near an opposite side of the main surface of the sapphire substrate.

7. The nitride semiconductor ultraviolet light emitting device according to claim 4, wherein the roughened surface band formed on the side surface of the sapphire substrate is uniformly distributed in a direction perpendicular to the main surface of the sapphire substrate.

8. The nitride semiconductor ultraviolet light emitting device according to claim 3, wherein, when a thickness of the sapphire substrate is X μm, a number of the roughened surface bands formed on the side surface of the sapphire substrate is X/200 or more.

9. The nitride semiconductor ultraviolet light emitting device according to claim 3, wherein, when a thickness of the sapphire substrate is X μm, a number of the roughened surface bands formed on the side surface of the sapphire substrate is X/150 or more.

10. A method for manufacturing an nitride semiconductor ultraviolet light emitting device, the nitride semiconductor ultraviolet light emitting device comprising:
a base;
a nitride semiconductor ultraviolet light emitting element flip-chip mounted on the base; and
an amorphous fluororesin that is in direct contact with the nitride semiconductor ultraviolet light emitting element for covering,
wherein:
the nitride semiconductor ultraviolet light emitting element comprises a sapphire substrate, a plurality of AlGaN-based semiconductor layers laminated on a main surface of the sapphire substrate, an n-electrode composed of one or a plurality of metal layers, and a p-electrode composed of one or a plurality of metal layers, and
a terminal functional group of the amorphous fluororesin is a perfluoroalkyl group, and
wherein the method comprises:
a first step of making laser light having a wavelength passing through the sapphire substrate incident from an opposite side of a main surface of the sapphire substrate, and condensing light in the sapphire substrate to cause damage to a surface to be cut in the sapphire substrate;
a second step of cutting the sapphire substrate at the surface to be cut to obtain a side surface of the sapphire substrate from which the depressions are exposed;
a third step of applying a coating solution obtained by dissolving the amorphous fluororesin in a predetermined solvent so as to coat an exposed surface of each of the nitride semiconductor ultraviolet light emitting element and the base with the coating solution to fill a gap part between the nitride semiconductor ultraviolet light emitting element and the base; and
a fourth step of evaporating the solvent to form a layer made of the amorphous fluororesin covering the exposed surface of each of the nitride semiconductor ultraviolet light emitting element and the base, filling the gap part between the nitride semiconductor ultraviolet light emitting element and the base, and entering into the depressions formed on the side surface of the sapphire substrate.

11. The method for manufacturing the nitride semiconductor ultraviolet light emitting device according to claim 10, wherein a roughened surface band formed by intermittently or continuously connecting the depressions is formed on the side surface of the sapphire substrate.

12. The method for manufacturing the nitride semiconductor ultraviolet light emitting device according to claim 11, wherein the roughened surface band formed on the side surface of the sapphire substrate extends along a direction having a component parallel to the main surface of the sapphire substrate.

13. The method for manufacturing the nitride semiconductor ultraviolet light emitting device according to claim 12, wherein a plurality of the roughened surface bands are formed on the side surface of the sapphire substrate.

14. The method for manufacturing the nitride semiconductor ultraviolet light emitting device according to claim 13, wherein the roughened surface band formed on the side surface of the sapphire substrate is unevenly distributed near the main surface side of the sapphire substrate.

15. The method for manufacturing the nitride semiconductor ultraviolet light emitting device according to claim 13, wherein the roughened surface band formed on the side surface of the sapphire substrate is unevenly distributed near an opposite side of the main surface of the sapphire substrate.

16. The method for manufacturing the nitride semiconductor ultraviolet light emitting device according to claim 13, wherein the roughened surface band formed on the side surface of the sapphire substrate is uniformly distributed in a direction perpendicular to the main surface of the sapphire substrate.

17. The method for manufacturing the nitride semiconductor ultraviolet light emitting device according to claim 12, wherein, when a thickness of the sapphire substrate is X □m, a number of the roughened surface bands formed on the side surface of the sapphire substrate is X/200 or more.

18. The method for manufacturing the nitride semiconductor ultraviolet light emitting device according to claim 12, wherein, when a thickness of the sapphire substrate is X □m, a number of the roughened surface bands formed on the side surface of the sapphire substrate is X/150 or more.
